(19) United States
(12) Patent Application Publication
(10) Pub. No.: US 2014/0150853 A1
(43) Pub. Date: Jun. 5, 2014

(54) SOLAR CELL APPARATUS

(71) Applicant: LG INNOTEK CO., LTD., Seoul (KR)

(72) Inventors: Dong Keun Lee, Seoul (KR); Myoung Seok Sung, Seoul (KR)

(73) Assignee: LG INNOTEK CO., LTD., Seoul (KR)

(21) Appl. No.: 14/174,446

(22) Filed: Feb. 6, 2014

Related U.S. Application Data
(63) Continuation of application No. 13/319,490, filed on Nov. 8, 2011.

(30) Foreign Application Priority Data
Oct. 28, 2009 (KR) 10-2009-0103078

(51) Int. Cl. H01L 31/048

(52) U.S. Cl. CPC H01L 31/048
USPC 136/251

(57) ABSTRACT

Disclosed is a solar cell apparatus. The solar cell apparatus includes: a solar cell panel including a central region and an outer region surrounding the central region; a first adhesive member adhered to the central region; a second adhesive member adhered to the outer region and having an adhesive strength greater than the first adhesive member.

### CROSS-REFERENCE TO RELATED APPLICATIONS

This application is a continuation of U.S. application Ser. No. 13/319,490, filed Nov. 8, 2011, which is the U.S. national stage application of International Patent Application No. PCT/KR2010/007492, filed Oct. 28, 2010, which claims priority to Korean Application No. 10-2009-0103078, filed Oct. 28, 2009, the disclosures of each of which are incorporated herein by reference in their entirety.

### BACKGROUND

The present disclosure relates to a solar cell apparatus.

Solar cell modules for converting light energy to electric energy by using a photoelectric conversion effect are widely used as a means for obtaining environmentally friendly energy contributing to the earth environment preservation.

As the photoelectric conversion efficiency of a solar cell is improved, various solar cell systems including solar cell modules have been installed for residential use.

### BRIEF SUMMARY

Embodiments provide a solar cell apparatus with enhanced performance which facilitates recycling.

In one embodiment, a solar cell apparatus according to an embodiment includes a solar cell panel including a central region and an outer region surrounding the central region; a first adhesive member adhered to the central region; and a second adhesive member adhered to the outer region and having an adhesive strength greater than the first adhesive member.

In another embodiment, a solar cell apparatus according to an embodiment includes: a solar cell panel; a buffer member making direct contact with a top surface of the solar cell panel; an adhesive member disposed on the solar cell panel and making contact with an surrounding region of the buffer member in a top surface of the solar cell panel; and a protective panel disposed on the buffer member and the adhesive member.

In a further embodiment, a solar cell apparatus according to an embodiment includes: a solar cell panel including a central region and an outer region around the central region; an attachable member disposed on the central region; an adhesive member adhered to the outer region; and a protective panel covering the attachable member and the adhesive member.

The details of one or more embodiments are set forth in the accompanying drawings and the description below. Other features will be apparent from the description and drawings, and from the claims.

### BRIEF DESCRIPTION OF THE DRAWINGS

FIG. 1 is an exploded perspective view illustrating a solar cell module according to an embodiment.

FIG. 2 is a plane view illustrating a solar cell module according to an embodiment.

FIG. 3 is a cross-sectional view taken along line A-A′ of FIG. 2.

FIG. 4 is a cross-sectional view illustrating a solar cell module according to another embodiment.

FIG. 5 is a cross-sectional view illustrating a solar cell module according to still another embodiment.

### DETAILED DESCRIPTION

In the description of embodiments, it will be understood that when a substrate, a layer, a film, or an electrode is referred to as being ‘on’ or ‘under’ another substrate, layer, film, or electrode, the terminology of ‘on’ and ‘under’ includes both the meanings of ‘directly’ and ‘indirectly’. Further, the reference about ‘on’ and ‘under’ each component layer will be made on the basis of drawings. In addition, the sizes of elements and the relative sizes between elements may be exaggerated for further understanding of the present disclosure.

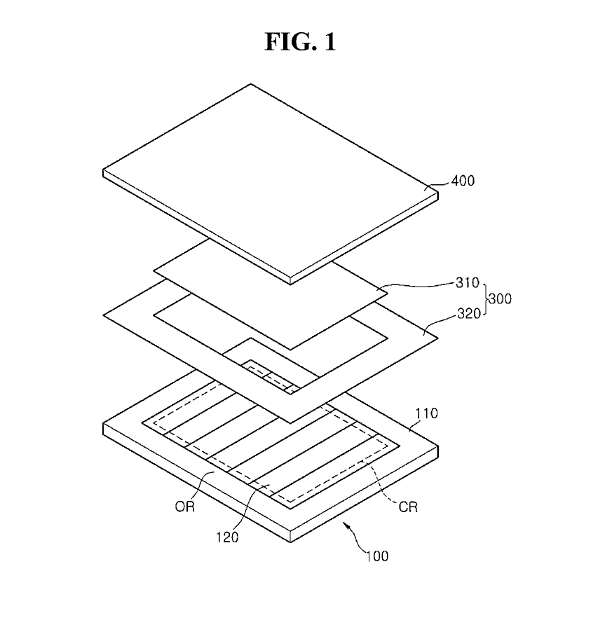

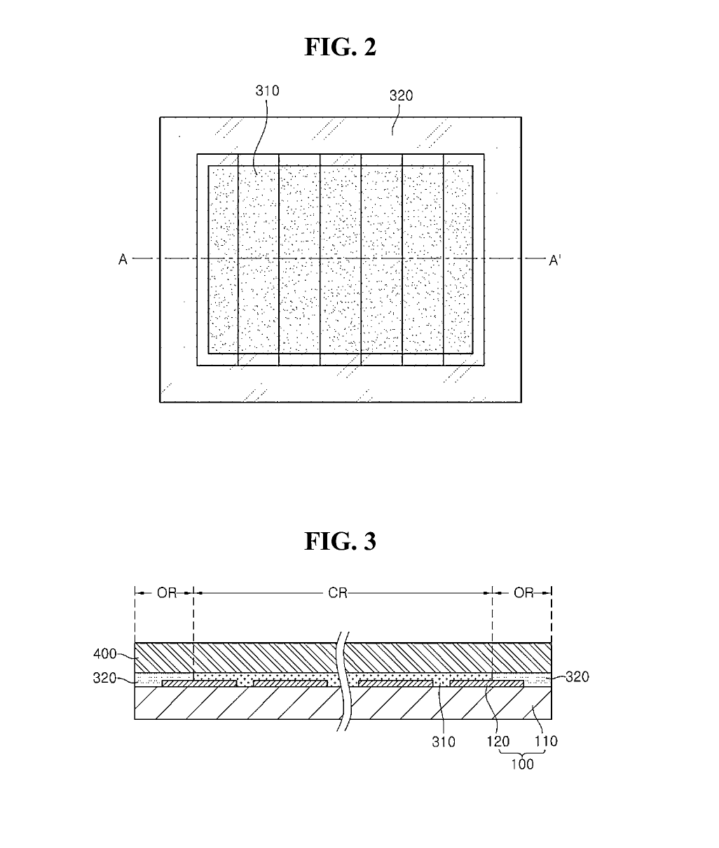

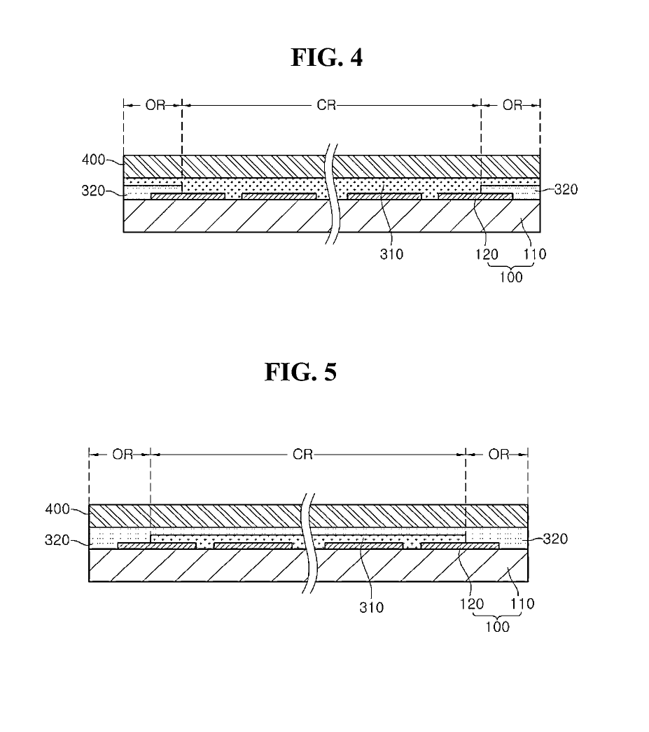

FIG. 1 is an exploded perspective view illustrating a solar cell module according to an embodiment. FIG. 2 is a plane view illustrating a solar cell module according to an embodiment. FIG. 3 is a cross-sectional view taken along line A-A′ of FIG. 2. FIG. 4 is a cross-sectional view illustrating a solar cell module according to another embodiment. FIG. 5 is a cross-sectional view illustrating a solar cell module according to still another embodiment.

Referring to FIGS. 1 to 3, a solar cell module according to an embodiment includes a solar cell panel 100, an adhesive member 300, and a protective panel 400.

The solar cell panel 100 has a plate shape. The solar cell panel 100 includes a central region CR and an outer region OR. The central region CR is defined as being a central portion of the solar cell panel 100, and the outer region OR is defined around the central region CR.

The solar cell panel 100 may be separated by the central region and the outer region OR. The solar cell panel 100 includes a support substrate 110 and a plurality of solar cells 120.

The support substrate 110 has a plate shape. The support substrate 110 is an insulator. The support substrate 110 may be rigid or flexible. For example, the support substrate 110 may be a soda lime glass substrate. Also, the support substrate 110 supports the solar cells 120.

The solar cells 120 are disposed on the support substrate 110. As illustrated in the drawings, the solar cells 120 may be disposed over the central region CR and the out region OR.

Alternatively, the solar cells 120 are disposed only on the central region CR.

The solar cells 120 receive solar light to convert the solar light to electric energy. The solar cells 120 are connected in series. And also, the solar cells 120 may have a shape extending to one direction.

For example, the solar cells 120 may be copper indium gallium selenide (CIGS) based solar cells, silicon based solar cells, or dye-sensitized solar cells.

The adhesive member 300 is disposed on the solar cell panel 100. The adhesive member 300 is disposed between the solar cell panel 100 and the protective panel 400. The adhesive member 300 adheres the solar cell panel 100 to the protective panel 400. That is, the adhesive member 300 is adhered to the top surface of the solar cell panel 100 and the bottom surface of the protective panel 400.

The adhesive member 300 includes a first adhesive member 310 and a second adhesive member 320.

The first adhesive member 310 is disposed on the central region CR. The first adhesive member 310 is disposed corresponding to the central region CR. The first adhesive member 310 adheres the central portion of the solar cell panel 100 to the central portion of the protective panel 400.

The first adhesive member 310 may be adhered to the central region CR. The first adhesive member 310 has a relatively low adhesive strength. That is, the first adhesive member 310 has an adhesive strength less than the second adhesive member 320. In more detail, an adhesive strength between the first adhesive member 310 and the solar cell panel 100 is low.

Thus, the first adhesive member 310 and the solar cell panel 100 are easily attachable/detachable. That is, the first adhesive member 310 is easily attachable/detachable to/from the solar cell panel 100 without the solar cells 120 being damaged.

The first adhesive member 310 may have a rectangular shape in terms of the plane. And also, the first adhesive member 310 is disposed inside the second adhesive member 320.

Ethylene vinyl acetate or polyurethane based adhesive may be used as the first adhesive member 310.

In this case, ethylene vinyl acetate which is used in the first adhesive member 310 have a relatively low content of vinyl acetate. For example, ethylene vinyl acetate which is used in the first adhesive member 310 have a relatively low content of vinyl acetate of about 15 wt % to about 40 wt %.

That is, to form ethylene vinyl acetate which is used in the first adhesive member 310, monomers or oligomers having about 15 wt % to about 40 wt % of vinyl acetate may be polymerized.

The first adhesive member 310 covers almost all of the solar cells 120. In more detail, the first adhesive member 310 may cover all of the solar cells 120.

The second adhesive member 320 is disposed on the outer region OR. The second adhesive member 320 has a closed-loop shape. For example, the second adhesive member 320 may have a rectangular loop shape in terms of the plane.

The second adhesive member 320 is disposed between the solar cell panel 100 and the protective panel 400. And also, the second adhesive member 320 is adhered to the bottom surface of the protective panel 400 and the top surface of the solar cell panel 100. The second adhesive member 320 is adhered to the outer region OR.

The second adhesive member 320 is disposed corresponding to the outer of the solar cell panel 100. That is, the second adhesive member 320 is disposed corresponding to the sides of the solar cell panel 100. That is, the adhesive member 320 may be disposed on the top surface of the solar cell panel 100 and have a shape extending along the sides of the solar cell panel 100.

The second adhesive member 320 may be adhered to some of the solar cells 120.

Alternatively, the second adhesive member 320 may be adhered only to an area in which the solar cells 120 are not disposed. That is, the second adhesive member 320 may not be adhered to the solar cells 120.

The second adhesive member 320 has a relatively high adhesive strength. That is, the second adhesive member 320 is adhered to the solar cell panel 100, with a high adhesive strength. The second adhesive member 320 has an adhesive strength much greater than the first adhesive member 310.

That is, the second adhesive member 320 is strictly adhered to the solar cell panel 100, with a high adhesive strength. Thus, the solar cells 120 may be damaged when the second adhesive member 320 is attached/detached to/from the solar cell panel 100.

Ethylene vinyl acetate, a ceramic based adhesive, or an epoxy based adhesive may be used as the second adhesive member 320.

In this case, ethylene vinyl acetate which is included in the second adhesive member 320 may have a relatively low content of vinyl acetate. That is, ethylene vinyl acetate which is included in the second adhesive member 320 may have a content of vinyl acetate greater than ethylene vinyl acetate which is included in the first adhesive member 310.

For example, ethylene vinyl acetate which is included in the second adhesive member 320 may have about 40 wt % to about 60 wt % of vinyl acetate.

The second adhesive member 320 may be a sealing member for sealing the space between the solar cell panel 100 and the protective panel 400. And also, the second adhesive member 310 may be a buffer member absorbing a shock which is applied from the outside through the protective panel 400. Furthermore, the first adhesive member 310 may not have an adhesive strength, but a buffer function.

That is, the second adhesive member 320 usually may protect the solar cells 120 from an external chemical shock such as humidity and/or oxygen. And also, the first adhesive member 310 usually may protect the solar cells 120 from an external physical shock.

The protective panel 400 is disposed on the adhesive member 300. The protective panel 400 is disposed on the solar cell panel 100. The protective panel 400 protects the solar cells 120 from an external physical shock and/or alien substances. The protective panel may be transparent and, for example, include tempered glass.

And also, another buffer layer may be disposed between the protective panel 400 and the adhesive member 300. In this case, the buffer layer may be transparent, and formed of an elastic polymer such as ethylene vinyl acetate (EVA).

Although not illustrated, the solar cell module according to an embodiment may further comprise a frame, bus bar, junction box, and cable.

The frame accommodates and supports the solar cell panel 100 and the protective panel 400. The frame fixes the support substrate and the protective panel 400.

The bus bar may be coupled to the top surface of the solar cell 120 and be connected to a circuit board in the junction box through wiring.

The junction box may be disposed on the bottom surface of the support substrate 110. The junction box may accommodate the circuit board with the diode installed therein. The solar cell module according to an embodiment, the cable is extended from the junction box. The cable is coupled to the bus bar through the circuit board accommodated in the junction box. And also, the cable is connected to another solar cell module.

In the solar cell module according to an embodiment, the first adhesive member 310 having a relatively low adhesive strength is disposed on the central region CR, and is adhered to the solar cell panel 100 and the protective panel 400. Moreover, the first adhesive member 310 covers almost all of the solar cells 120.

Thus, the first adhesive member 310 is easily attachable/detachable to/from the solar cell panel, and when the first adhesive member 310 is attached/detached to/from the solar cell panel 100, the solar cells 120 are barely damaged.

And also, since the second adhesive member 320 has a closed-loop shape and strong adhesive strength, a sealing area may be strictly formed between the solar cell panel 100 and the protective panel 400. Thus, an external alien substance is prevented from permeating the solar cell panel 100.

Accordingly, the solar cell module according to an embodiment is easily attachable/detachable to/from the first adhesive member 310 as the damage of the solar cell is minimized.

Thus, the solar cell module according to an embodiment can prevent performance degradation due to alien substances.

As illustrated in FIG. 4, the first adhesive member 310 may cover the second adhesive member 320. That is, the first adhesive member 310 may be disposed in the outer region OR in addition to the central region CR.

A portion of the first adhesive member 310 is disposed between the second adhesive member 320 and the protective panel 400. That is, a portion of the first adhesive member 310, which is disposed in the outer region OR, may be directly contacted to the top surface of the second adhesive member 320 and the bottom surface of the protective panel 400.

In the solar cell module of FIG. 4, the first adhesive member 310 and the second adhesive member 320 may be easily attached onto the solar cell panel 100. That is, unlike in FIGS. 1 to 3, in the solar cell module of FIG. 4, the first adhesive member 310 is not necessary to be aligned inside the second adhesive member 320.

Accordingly, the solar cell module of FIG. 4 having performance equivalent to the solar cell module of FIGS. 1 to 3 can be easily manufactured.

And also, as illustrated in FIG. 5, the second adhesive member 320 may cover the first adhesive member 310. That is, the second adhesive member 320 may entirely cover the top surface of the solar cell panel 100.

In this case, the second adhesive member 320 is contacted with the outer region OR directly, but not the central region CR. That is, the first adhesive member 310 is disposed between the second adhesive member 320 and the central region CR.

And also, the first adhesive member 310 is adhered to the protective panel 400 through the second adhesive member 320. Thus, the first adhesive member 310 may be strictly adhered to the protective panel 400.

Furthermore, the first adhesive member 310 and the second adhesive member 320 are not necessary to be aligned to each other, thereby easily manufacturing the solar cell module of FIG. 5.

In the solar cell apparatus according to an embodiment, the protective panel can be adhered only to the outer portion of the solar cell panel, using the second adhesive member of a closed-loop shape.

And also, in the solar cell apparatus according to an embodiment, the protective panel can be adhered only to the central portion of the solar cell panel, using the first adhesive member with a relatively low adhesive strength.

Thus, since the adhesive strength in the central portion is low, the first adhesive member and solar cell panel are easily attachable to each other.

That is, since the protective panel and the central portion of the solar cell panel are attached to the attachable member, most of the solar cells are attached to the attachable member. Thus, the solar cell apparatus according to an embodiment is recyclable. Then, the attachable member or the first adhesive member can be removed without most of the solar cells being damaged. Thus, in the solar cell apparatus according to an embodiment, the solar cells are effectively recyclable.

Furthermore, the outer region is adhered using a second adhesive member with a high adhesive strength, and thus solar cell apparatus according to an embodiment can easily prevent permeation of alien substance.

The solar cell module according to an embodiment is used in the solar cell field.

Any reference in this specification to “one embodiment,” “an embodiment,” “exemplary embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell apparatus comprising:
a solar cell panel;
a buffer member making direct contact with the top surface of the solar cell panel;
an adhesive member disposed on the solar cell panel and adhered to a surrounding region of the buffer member in a top surface of the solar cell panel; and
a protective panel disposed on the buffer member and the adhesive member, wherein the adhesive member has an area greater than the buffer member.

2. The solar cell apparatus of claim 1, wherein the adhesive member has a closed- loop.

3. The solar cell apparatus of claim 1, wherein the adhesive member surrounds the buffer member.

4. The solar cell apparatus of claim 1, wherein the adhesive member covers side and top surfaces of the buffer member.

5. The solar cell apparatus of claim 1, wherein the adhesive member comprises ethylene vinyl acetate which has about 40 wt % to 60 wt % of vinyl acetate.

6. The solar cell apparatus of claim 1, wherein the buffer member has an adhesive strength less than the adhesive member.

7. The solar cell apparatus of claim 1, wherein the buffer member is attachable/detachable to/from the solar cell panel.
